(19) United States
(12) Patent Application Publication
(10) Pub. No.: US 2026/0096336 A1
(43) Pub. Date: Apr. 2, 2026

(54) Display Device

(71) Applicant: LG Display Co., Ltd., Seoul (KR)

(72) Inventor: JaeHyung Jo, Goyang-si (KR)

(21) Appl. No.: 19/255,883

(22) Filed: Jun. 30, 2025

(30) Foreign Application Priority Data
Sep. 27, 2024 (KR) 10-2024-0131841

(51) Int. Cl. H10K 59/80; G09G 3/3233; H10K 59/131

(52) U.S. Cl. CPC H10K 59/8792; H10K 59/131; H10K 59/879; G09G 3/3233; G09G 2300/0426; G09G 2300/0842; G09G 2320/0233; G09G 2320/029; G09G 2320/045

(57) ABSTRACT

A display device is disclosed. The display device includes a substrate and a plurality of sub pixels on the substrate. Each of the plurality of sub pixels includes an emission area and a non-emission area. A metal layer is disposed on the substrate and is closer to the substrate than other metal layers of the display device. A transmission reduction layer that reduces transmission of external light is between the metal layer and the substrate. The transmission reduction layer has a first surface that is black and less smooth than a second surface of the transmission reduction layer.

### CROSS-REFERENCE TO RELATED APPLICATION

This application claims the priority of Republic of Korea Patent Application No. 10-2024-0131841 filed on Sep. 27, 2024, which is hereby incorporated by reference in its entirety.

### BACKGROUND

### Field

The present disclosure relates to a display device, and more particularly, to a display device which minimizes or at least reduces reflection of external light.

### Description of the Related Art

Currently, as it enters a full-scale information era, a field of a display device which visually expresses electrical information signals has been rapidly developed and studies are continued to improve performances of various display devices such as thin-thickness, light weight, and low power consumption.

A representative display device may include a liquid crystal display device (LCD), a field emission display device (FED), an electro-wetting display device (EWD), and an organic light emitting display device (OLED).

Among them, the organic light emitting display device is a self-emitting display device so that a separate light source is not necessary, which is different from the liquid crystal display device. Therefore, the organic light emitting display device may be manufactured to have a light weight and a small thickness. Further, since the organic light emitting display device is advantageous not only in terms of power consumption due to the low voltage driving, but also in terms of color implementation, a response speed, a viewing angle, and a contrast ratio (CR), it is expected to be utilized in various fields.

### SUMMARY

An object to be achieved by the present disclosure is to provide a display device which minimizes or at least reduces reflection of external light.

Another object to be achieved by the present disclosure is to provide a display device which reduces a line load.

Still another object to be achieved by the present disclosure is to provide a display device which improves optical reliability and thermal stability of a transistor.

Objects of the present disclosure are not limited to the above-mentioned objects, and other objects, which are not mentioned above, can be clearly understood by those skilled in the art from the following descriptions.

In one embodiment, a display device comprises: a substrate; a plurality of sub pixels on the substrate, each of the plurality of sub pixels including an emission area and a non-emission area; a metal layer on the substrate, the metal layer closer to the substrate than other metal layers of the display device; and a transmission reduction layer that reduces transmission of external light, the transmission reduction layer between the metal layer and the substrate and having a first surface that is black and less smooth than a second surface of the transmission reduction layer.

In one embodiment, a display device comprises: a substrate; a plurality of sub pixels on the substrate, each of the plurality of sub pixels including an emission area and a non-emission area; a metal layer on the substrate, the metal layer including a plurality of wiring lines and a light shielding layer that are on the substrate; and a transmission reduction layer that reduces transmission of external light, the transmission reduction layer including a conductive material and has a first surface that is black and less smooth than a second surface of the transmission reduction layer, wherein the transmission reduction layer is between the metal layer and the substrate such that the transmission reduction layer overlaps the metal layer.

In one embodiment, a display device comprises: a substrate; a conductive transmission reduction layer that is in contact with an upper surface of the substrate, the conductive transmission reduction layer having a first surface and a second surface that is smoother than the first surface and the first surface is less transmissive of external light than the second surface; a metal layer directly on the first surface of the conductive transmission reduction layer such that the conductive transmission reduction layer is between the metal layer and the substrate; a transistor on the substrate; and a light emitting element that emits light, the light emitting element electrically connected to the transistor.

Other detailed matters of the exemplary embodiments are included in the detailed description and the drawings.

According to the present disclosure, in the display device, a transmission reduction layer is disposed between a metal layer which is disposed to be the closest to the substrate and the substrate to suppress transmission of external light reflected by the wiring lines and electrodes, thereby minimizing or at least reducing the reflection of external light.

According to the present disclosure, in the display device, a transmission reduction layer which is connected to a wiring line is disposed in an area where a line load is increased to reduce the resistance, thereby reducing the line load.

According to the present disclosure, the display device minimizes transmission of ultraviolet light to improve the optical reliability and the thermal stability of the transistor.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a display device according to an exemplary embodiment of the present disclosure;

FIG. 2 is a circuit diagram of a sub pixel of a display device according to an exemplary embodiment of the present disclosure;

FIG. 3 is a plan view of a display device according to an exemplary embodiment of the present disclosure;

FIG. 4 is a cross-sectional view for A-A′ of FIG. 3 according to an exemplary embodiment of the present disclosure;

FIG. 5 is a plan view of a display device according to another exemplary embodiment of the present disclosure;

FIG. 6 is a cross-sectional view for B-B′ of FIG. 5 according to an exemplary embodiment of the present disclosure;

FIG. 7 is a plan view of a display device according to still another exemplary embodiment of the present disclosure;

FIG. 8 is a cross-sectional view for C-C′ of FIG. 7 according to an exemplary embodiment of the present disclosure;

FIG. 9 is a plan view of a display device according to still another exemplary embodiment of the present disclosure; and

FIG. 10 is a cross-sectional view for D-D′ of FIG. 9 according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When explaining temporal relationships, terms such as “after,” “following,” “subsequent to,” or “before,” etc., may include non-consecutive cases unless terms like “immediately” or “directly” are used.

Terms such as “first,” “second,” etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “X-axis direction”, “Y-axis direction”, and “Z-axis direction” should not be interpreted solely as geometric relationships perpendicular to each other, but may indicate broader directionality within the range where the configuration of the present disclosure can function.

The features of various embodiments in the present disclosure may be partially or wholly combined or associated with each other, various technical interlocking and operations are possible, and each embodiment may be implemented independently of each other or may be implemented together in an associated relationship.

Hereinafter, a display apparatus according to exemplary embodiments of the present disclosure will be described in detail with reference to accompanying drawings.

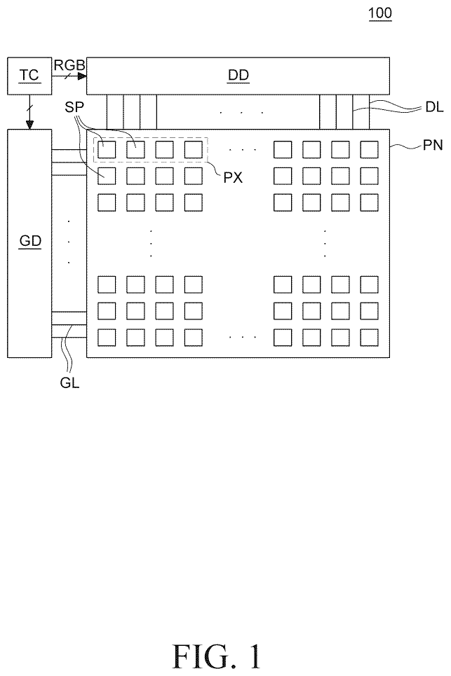

FIG. 1 is a block diagram of a display device according to an exemplary embodiment of the present disclosure.

Referring to FIG. 1, a display device 100 includes a display panel PN, a gate driver GD, a data driver DD, and a timing controller TC.

The display panel PN is a panel for displaying images. The display panel PN may include various circuits, wiring lines, and light emitting diodes disposed on the substrate. The display panel PN is divided by a plurality of data lines DL and a plurality of gate lines GL intersecting each other and may include a plurality of pixels PX connected to the plurality of data lines DL and the plurality of gate lines GL.

The display panel PN may include a display area defined by a plurality of pixels PX and a non-display area in which various signal lines or pads are formed. The display panel PN may be implemented by a display panel PN used in various display devices such as a liquid crystal display device, an organic light emitting display device, or an electrophoretic display device. Hereinafter, it is described that the display panel PN is a panel used for an organic light emitting display device, but is not limited thereto.

The timing controller TC may receive timing signals such as a vertical synchronization signal, a horizontal synchronization signal, a data enable signal, or a dot clock by means of a receiving circuit such as an LVDS or TMDS interface connected to a host system. The timing controller TC generates timing control signals based on the input timing signal to control the data driver DD and the gate driver GD.

The data driver DD supplies a data voltage to the plurality of sub pixels SP. The data driver DD may include a plurality of source drive ICs (integrated circuits). The plurality of source drive ICs may be supplied with digital video data and a source timing control signal from the timing controller TC. The plurality of source drive ICs converts digital video data into a gamma voltage in response to the source timing control signal to generate a data voltage and supply the data voltage through the data line DL of the display panel PN. The plurality of source drive ICs may be connected to the data line DL of the display panel PN by a chip on glass (COG) process or a tape automated bonding (TAB) process. Further, the source drive ICs are formed on the display panel PN or are formed on a separate PCB substrate to be connected to the display panel PN.

The gate driver GD supplies a gate signal to the plurality of sub pixels SP. The gate driver GD may include a level shifter and a shift register. The level shifter shifts a level of a clock signal input at a transistor-transistor-logic (TTL) level from the timing controller TC and then supplies the clock signal to the shift register. The shift register may be formed in the non-display area of the display panel PN, by a GIP manner, but is not limited thereto. The shift register may be configured by a plurality of stages which shifts the gate signal to output, in response to the clock signal and the driving signal. The plurality of stages included in the shift register may sequentially output the gate signal through a plurality of output terminals.

The display panel PN may include a plurality of sub pixels SP. The plurality of sub pixels SP may be sub pixels SP for emitting different color light. For example, the plurality of sub pixels SP may be a red sub pixel, a green sub pixel, a blue sub pixel, and a white sub pixel, but is not limited thereto. The plurality of sub pixels SP may configure a pixel PX. That is, the red sub pixel, the green sub pixel, the blue sub pixel, and the white sub pixel may configure one pixel PX and the display panel PN may include a plurality of pixels PX.

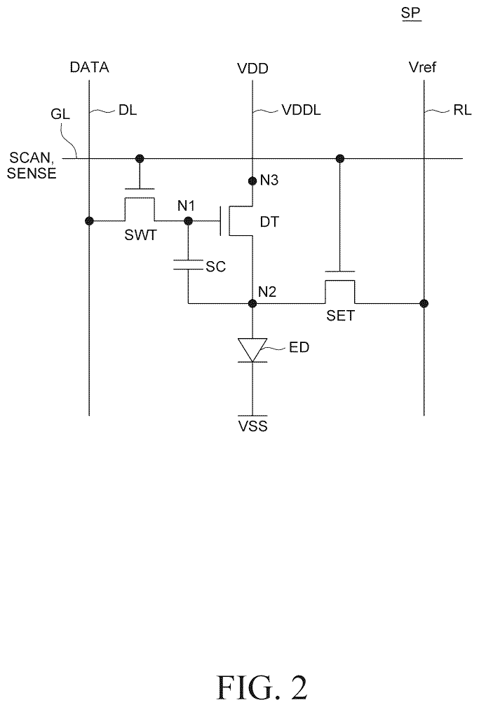

Hereinafter, a driving circuit for driving one sub pixel SP will be described in more detail with reference to FIG. 2 together.

FIG. 2 is a circuit diagram of a sub pixel of a display device according to an exemplary embodiment of the present disclosure. In FIG. 2, a circuit diagram for one sub pixel SP among the plurality of sub pixels SP of the display device 100 is illustrated.

Referring to FIG. 2, the sub pixel SP may include a switching transistor SWT, a sensing transistor SET, a driving transistor DT, a storage capacitor SC, and a light emitting diode ED.

The light emitting diode ED may include an anode, an organic layer, and a cathode. The organic layer may include various organic layers, such as a hole injection layer, a hole transport layer, an organic emission layer, an electron transport layer, and an electron injection layer. The anode of the light emitting diode ED may be connected to an output terminal of the driving transistor DT and a low potential voltage VSS may be applied to the cathode. Even though in FIG. 2, it is described that the light emitting diode ED is an organic light emitting diode, the present disclosure is not limited thereto so that as the light emitting diode ED, an inorganic light emitting diode, that is, an LED may also be used.

The switching transistor SWT is a transistor which transmits the data voltage DATA to a first node N1 corresponding to a gate electrode of the driving transistor DT. The switching transistor SWT may include a drain electrode connected to the data line DL, a gate electrode connected to the gate line GL, and a source electrode connected to the gate electrode of the driving transistor DT. The switching transistor SWT is turned on by a scan signal SCAN applied from the gate line GL to transmit a data voltage DATA supplied from the data line DL to the first node N1 corresponding to the gate electrode of the driving transistor DT.

The driving transistor DT is a transistor which supplies a driving current to the light emitting diode ED to drive the light emitting diode ED. The driving transistor DT may include a gate electrode corresponding to the first node N1, a source electrode corresponding to a second node N2 and an output terminal, and a drain electrode corresponding to a third node N3 and an input terminal. The gate electrode of the driving transistor DT is connected to the switching transistor SWT, the drain electrode is applied with a high potential voltage VDD by means of a high potential voltage line VDDL, and the source electrode may be connected to the anode of the light emitting diode ED.

A storage capacitor SC is a capacitor which maintains a voltage corresponding to the data voltage DATA for one frame. One electrode of the storage capacitor SC is connected to the first node N1 and the other electrode may be connected to the second node N2.

In the meantime, in the case of the display device 100, as the driving time of each sub pixel SP is increased, the circuit element such as the driving transistor DT may be degraded. Accordingly, a unique characteristic value of the circuit element, such as a driving transistor DT, may be changed. Here, the unique characteristic value of the circuit element may include a threshold voltage Vth of the driving transistor DT or a mobility a of the driving transistor DT. The change in the characteristic value of the circuit element may cause a luminance change of the corresponding sub pixel SP. Accordingly, the change in the characteristic value of the circuit element may be used as the same concept as the luminance change of the sub pixel SP.

Further, the degree of the change in the characteristic values between circuit elements of each sub pixel SP may vary depending on a degree of degradation of each circuit element. Such a difference in the changed degree of the characteristic values between the circuit elements may cause a luminance deviation between the sub pixels SP. Accordingly, the characteristic value deviation between circuit elements may be used as the same concept as the luminance deviation between the sub pixels SP. The change in the characteristic values of the circuit elements, that is, the luminance change of the sub pixel SP and the characteristic value deviation between the circuit elements, that is, the luminance deviation between the sub pixels SP may cause problems such as the lowering of the accuracy for luminance expressiveness of the sub pixel SP or screen abnormality.

Therefore, the sub pixel SP of the display device 100 according to the exemplary embodiment of the present disclosure may provide a sensing function of sensing a characteristic value for the sub pixel SP and a compensating function of compensating for the characteristic value of the sub pixel SP using the sensing result.

Accordingly, the sub pixel SP may further include a sensing transistor SET to effectively control a voltage state of the source electrode of the driving transistor DT, in addition to the switching transistor SWT, the driving transistor DT, the storage capacitor SC, and the light emitting diode ED.

The sensing transistor SET is connected between the source electrode of the driving transistor DT and the reference line RL which supplies a reference voltage Vref and a gate electrode is connected to the gate line GL. Therefore, the sensing transistor SET is turned on by the sensing signal SENSE applied through the gate line GL to apply the reference voltage Vref which is supplied through the reference line RL to the source electrode of the driving transistor DT. Further, the sensing transistor SET may be utilized as one of voltage sensing paths for the source electrode of the driving transistor DT.

Accordingly, the reference voltage Vref is applied to the source electrode of the driving transistor DT by means of the sensing transistor SET. Further, a voltage for sensing the threshold voltage Vth of the driving transistor DT or the mobility a of the driving transistor DT is detected by the reference line RL. Further, the data driver DD may compensate for the data voltage DATA in accordance with a variation of the detected threshold voltage Vth of the driving transistor DT or the detected mobility a of the driving transistor DT.

The switching transistor SWT and the sensing transistor SET of the sub pixel SP may share one gate line GL. That is, the switching transistor SWT and the sensing transistor SET are applied to the same gate line GL to be applied with the same gate signal. However, for the convenience of description, a voltage which is applied to the gate electrode of the switching transistor SWT is referred to as a scan signal SCAN and a voltage which is applied to the gate electrode of the sensing transistor SET is referred to as a sensing signal SENSE. However, the scan signal SCAN and the sensing signal SENSE applied to one sub pixel SP are the same signal which is transmitted from the same gate line GL. However, the present disclosure is not limited thereto so that only the switching transistor SWT is connected to the gate line GL and the sensing transistor SET may be connected to a separate sensing line. The scan signal SCAN may be applied to the switching transistor SWT through the gate line GL and the sensing signal SENSE may be applied to the sensing transistor SET through the sensing line.

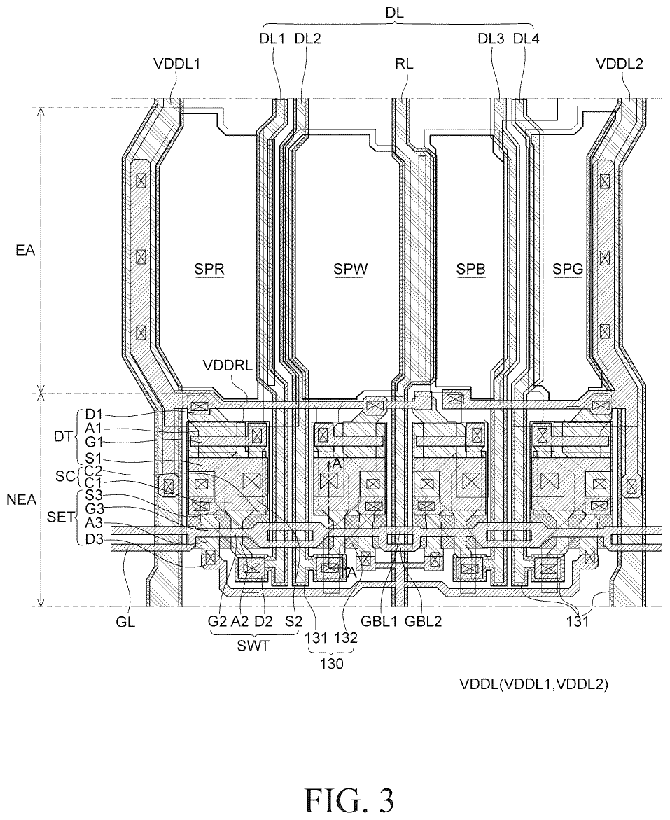

FIG. 3 is a plan view of a display device according to an exemplary embodiment of the present disclosure. FIG. 3 illustrates only one pixel PX for the convenience of description.

Referring to FIG. 3, the plurality of sub pixels SP of the display device 100 according to the exemplary embodiment of the present disclosure includes a red sub pixel SPR, a white sub pixel SPW, a blue sub pixel SPB, and a green sub pixel SPG. For example, the green sub pixel SPG and the white sub pixel SPW have higher light efficiency and luminance contribution so that the size thereof is lower than the red sub pixel SPR and the blue sub pixel SPB.

Each sub pixel SP includes an emission area EA and a non-emission area NEA.

The emission area EA is an area where one color light is independently emitted and the light emitting diode ED may be disposed therein. An emission area EA of the red sub pixel SPR is a red emission area which emits red light and an emission EA of the white sub pixel SPW is a white emission area which emits white light. An emission area EA of the blue sub pixel SPB is a blue emission area which emits blue light and an emission area EA of the green sub pixel SPG is a green emission area which emits green light.

In each of the sub pixels SP, the emission area EA is formed on the anode electrode of the light emitting diode ED to be defined by a bank which exposes a part of the anode electrode. That is, the anode electrode exposed by the bank may be defined as an emission area EA of each of the sub pixels SP.

The non-emission area NEA is an area in which a driving circuit for driving the plurality of light emitting diodes ED is disposed and for example, the switching transistor SWT, the sensing transistor SET, the driving transistor DT, and the storage capacitor SC may be disposed. For example, the emission area EA and the non-emission area NEA may be disposed along a second direction (column direction) which is perpendicular to a first direction (row direction). In each of the sub pixels SP, the light emitting diode ED is driven by the pixel circuit provided in the non-emission area NEA to emit light. For example, the non-emission area NEA may also be referred to as a circuit unit.

Wiring lines connected to the sub pixel SP and electrodes which configure the transistor may be disposed on the same layer or different layers with one or more insulating layers therebetween and are electrically connected to each other through a contact hole which passes through the insulating layer for electrical connection.

In the non-emission area EA, a wiring line for applying a driving signal to each of the sub pixels SP may be included. The wiring lines may include a wiring line extending in the first direction and wiring lines extending in a second direction. The wiring line extending in the first direction may intersect the wiring lines extending in a second direction.

Referring to FIG. 3 together, the wiring line extending in the first direction may include a gate line GL. The gate line GL is a wiring line which transmits a scan signal SCAN and a sensing signal SENSE to each sub pixel SP. For example, the gate line GL may be commonly connected to the red sub pixel SPR, the white sub pixel SPW, the blue sub pixel SPB, and the green sub pixel SPG. For example, the gate line GL may be configured by a conductive material, such as copper (Cu), aluminum (Al), molybdenum (Mo), nickel (Ni), titanium (Ti), chrome (Cr), or an alloy thereof, but is not limited thereto. Specifically, the gate line GL may use a gate redundancy structure in an area which intersects a plurality of signal lines. The gate redundancy structure is a structure in which the gate line GL is branched into two lines only in an area in which the gate line GL and the plurality of signal lines intersect. The gate redundancy structure may include a first bridge line GBL1 which extends along the gate line GL and then is downwardly branched with respect to the column direction and a second bridge line GBL2 which is upwardly branched.

The wiring line extending in the second direction may include a high potential power line VDDL, a plurality of data lines DL, and a reference line RL. The wiring line extending in the second direction may extend to the second direction across the sub pixels SP which are adjacent to each other in the first direction.

The high potential power line VDDL, the data line DL, and the reference line RL are disposed on the same layer on the substrate 110 to be formed of the same material. For example, the high potential power line VDDL, the data line DL, and the reference line RL may be configured by a conductive material, such as copper (Cu), aluminum (Al), molybdenum (Mo), nickel (Ni), titanium (Ti), chrome (Cr), or an alloy thereof, but are not limited thereto.

The high potential power line VDDL is a wiring line which transmits a power signal to each of the plurality of sub pixels SP. For example, the plurality of sub pixels SP may share two high potential power lines VDDL. For example, the first high potential power line VDDL1 is disposed at a left side of the red sub pixel SPR to be connected to the red sub pixel SPR and the white sub pixel SPW. The second high potential power line VDDL2 is disposed at a right side of the green sub pixel SPG to be connected to the blue sub pixel SPB and the green sub pixel SPG.

The plurality of data lines DL is wiring lines which transmit a data signal to each of the plurality of sub pixels SP and may include a first data line DL1, a second data line DL2, a third data line DL3, and a fourth data line DL4.

The first data line DL1 may be disposed between the red sub pixel SPR and the white sub pixel SPW. For example, the first data line DL1 is disposed at the right side of the red sub pixel SPR and is connected to the red sub pixel SPR to apply a data voltage.

The second data line DL2 may be disposed between the red sub pixel SPR and the white sub pixel SPW. For example, the second data line DL2 is disposed at the left side of the white sub pixel SPW to be connected to the white sub pixel SPW to apply a data voltage.

The third data line DL3 may be disposed between the blue sub pixel SPB and the green sub pixel SPG. For example, the third data line DL3 is disposed at the right side of the blue sub pixel SPB and is connected to the blue sub pixel SPB to apply a data voltage.

The fourth data line DL4 may be disposed between the blue sub pixel SPB and the green sub pixel SPG. For example, the fourth data line DL4 is disposed at the left side of the green sub pixel SPG and is connected to the green sub pixel SPG to apply a data voltage.

The reference line RL transmits a reference signal to each of the plurality of sub pixels SP and may be disposed between the white sub pixel SPW and the blue sub pixel SPB. The plurality of sub pixels SP which forms one pixel PX may share one reference line RL. For example, the reference line RL may be connected to the red sub pixel SPR, the white sub pixel SPW, the blue sub pixel SPB, and the green sub pixel SPG through a reference branch line RBL. For example, the reference line RL is connected to the red sub pixel SPR, the white sub pixel SPW, the blue sub pixel SPB, and the green sub pixel SPG to apply a reference voltage.

Referring to FIGS. 2 and 3, the driving transistor DT may be disposed in the non-emission area NEA of each of the red sub pixel SPR, the white sub pixel SPW, the blue sub pixel SPB, and the green sub pixel SPG.

The driving transistor DT may include a first gate electrode G1, a first source electrode S1, a first drain electrode D1, and a first active layer A1.

The driving transistor DT may be electrically connected to the first high potential power line VDDL1. For example, the first drain electrode D1 of the driving transistor DT may be connected to the first high potential power line VDDL1. The first drain electrode D1 may be integrated with a high potential power branch line VDDBL extending from the first high potential power line VDDL1. However, the present disclosure is not limited thereto so that when the first active layer A1 is conductively formed, the first drain electrode D1 may be connected to the high potential power branch line VDDLB extending from the second high potential power line VDDL2 through a contact hole.

The first active layer A1 may be formed of a semiconductor material, such as an oxide semiconductor, amorphous silicon, or polysilicon, but is not limited thereto. For example, when the first active layer A1 is formed of an oxide semiconductor, the first active layer A1 may be formed by a channel region, a source region, and a drain region and become conductive to serve as a first source electrode S1 and a first drain electrode D1. Alternatively, a transparent oxide layer is further disposed in a partial area on the first active layer A1 to become conductive to serve as the first source electrode S1 and the first drain electrode D1. At this time, the transparent oxide layer may be configured by a transparent conductive material, such as tin oxide (TO), indium tin oxide (ITO), indium zinc oxide (IZO), or indium tin zinc oxide (ITZO), but is not limited thereto.

The first source electrode S1 may be connected to the third source electrode S3 of the sensing transistor SET and the second electrode C2 of the storage capacitor SC. For example, the first source electrode S1 may be integrated with the third source electrode S3 of the sensing transistor SET and the second electrode C2 of the storage capacitor SC. However, the present disclosure is not limited thereto and when the first active layer A1 is conductively formed, the first source electrode S1 may be electrically connected through a contact hole.

The first gate electrode G1 may be disposed so as to overlap the channel region of the first active layer A1. The first gate electrode G1 may be configured by a conductive material, such as copper (Cu), aluminum (Al), molybdenum (Mo), nickel (Ni), titanium (Ti), chrome (Cr), or an alloy thereof, but is not limited thereto.

The switching transistor SWT may be disposed in the non-emission area NEA of each of the red sub pixel SPR, the white sub pixel SPW, the blue sub pixel SPB, and the green sub pixel SPG.

The switching transistor SWT may include a second gate electrode G2, a second source electrode S2, a second drain electrode D2, and a second active layer A2.

The switching transistor SWT may be electrically connected to one data line DL, among the plurality of data lines DL. For example, the second drain electrode D2 of the switching transistor SWT may be electrically connected to the data line DL. The second drain electrode D2 may be integrated with one data line DL among the plurality of data lines DL. However, the present disclosure is not limited thereto and when the second active layer A2 is conductively formed, the second drain electrode D2 may be connected to one data line DL, among the plurality of data lines DL, through a contact hole.

The second active layer A2 may be formed of a semiconductor material, such as an oxide semiconductor, amorphous silicon, or polysilicon, but is not limited thereto. For example, when the second active layer A2 is formed of an oxide semiconductor, the second active layer A2 is formed by a channel region, a source region, and a drain region and becomes conductive to serve as a second source electrode S2 and a second drain electrode D2. Alternatively, a transparent oxide layer is further disposed in a partial area on the second active layer A2 to become conductive to serve as the second source electrode S2 and the second drain electrode D2. At this time, the transparent oxide layer may be configured by a transparent conductive material, such as tin oxide (TO), indium tin oxide (ITO), indium zinc oxide (IZO), or indium tin zinc oxide (ITZO), but is not limited thereto.

The second source electrode S2 may be connected to the first gate electrode G1 of the driving transistor DT and the first electrode C1 of the storage capacitor SC. For example, the second source electrode S2 may be integrated with the first electrode C1 of the storage capacitor SC. However, the present disclosure is not limited thereto and when the second active layer A2 is conductively formed, the second source electrode S2 may be electrically connected to the first electrode C1 of the storage capacitor SC and the first gate electrode G1 of the driving transistor DT through a contact hole.

The second gate electrode G2 may be disposed so as to overlap the channel region of the second active layer A2. The second gate electrode G2 may be the gate line GL. For example, a part of the gate line GL may serve as the second gate electrode G2. The gate line GL may be configured by a conductive material such as copper (Cu), aluminum (Al), molybdenum (Mo), nickel (Ni), titanium (Ti), chrome (Cr), or an alloy thereof, but is not limited thereto.

The gate line GL transmits a gate signal to each of the plurality of sub pixels SP and extends in a row direction to traverse the plurality of sub pixels SP. For example, the gate line GL extends between the non-emission area NEA and the emission area EA of each of the plurality of sub pixels SP in the row direction to intersect the plurality of high potential power lines VDDL, the plurality of data lines DL, and the plurality of reference lines RL extending in the column direction.

The sensing transistor SET may be disposed in the non-emission area NEA of each of the red sub pixel SPR, the white sub pixel SPW, the blue sub pixel SPB, and the green sub pixel SPG.

The sensing transistor SET may include a third gate electrode G3, a third source electrode S3, a third drain electrode D3, and a third active layer A3.

The sensing transistor SET may be electrically connected to the reference line RL. For example, the third drain electrode D3 of the sensing transistor SET may be electrically connected to the reference branch line RBL extending from the reference line RL. The third drain electrode D3 may be integrated with the reference branch line RBL. However, the present disclosure is not limited thereto and when the third active layer A3 is conductively formed, the third drain electrode D3 may be electrically connected to the reference branch line RBL through a contact hole.

The third active layer A3 may be formed of a semiconductor material such as an oxide semiconductor, amorphous silicon, or polysilicon, but is not limited thereto. For example, when the third active layer A3 is formed of an oxide semiconductor, the third active layer A3 is formed by a channel region, a source region, and a drain region and becomes conductive to serve as a third source electrode S3 and a third drain electrode D3. Alternatively, a transparent oxide layer is further disposed in a partial area on the third active layer A3 to become conductive to serve as the third source electrode S3 and the third drain electrode D3. At this time, the transparent oxide layer may be configured by a transparent conductive material, such as tin oxide (TO), indium tin oxide (ITO), indium zinc oxide (IZO), or indium tin zinc oxide (ITZO), but is not limited thereto.

The third source electrode S3 may be connected to the first source electrode S1 of the driving transistor DT and the second electrode C2 of the storage capacitor SC. For example, the third source electrode S3 may be integrated with the second electrode C2 of the storage capacitor SC. However, the present disclosure is not limited thereto and when the third active layer A3 is conductively formed, the third source electrode S3 may be electrically connected to the second electrode C2 of the storage capacitor SC and the first source electrode S1 of the driving transistor DT through a contact hole.

The third gate electrode G3 may be disposed so as to overlap the channel region of the third active layer A3. The third gate electrode G3 may be the gate line GL. For example, a part of the gate line GL may serve as the third gate electrode G3. The gate line GL may be configured by a conductive material such as copper (Cu), aluminum (Al), molybdenum (Mo), nickel (Ni), titanium (Ti), chrome (Cr), or an alloy thereof, but is not limited thereto.

The storage capacitor SC may be disposed in the non-emission area NEA of each of the red sub pixel SPR, the white sub pixel SPW, the blue sub pixel SPB, and the green sub pixel SPG. The storage capacitor SC may store a voltage between the first gate electrode G1 and the first source electrode S1 of the driving transistor DT to allow the light emitting diode ED to continuously maintain a constant state for one frame. The storage capacitor SC includes a first electrode C1 and a second electrode C2.

The first electrode C1 may be a conductive area of the second active layer A2 in which the semiconductor layer and the transparent oxide layer are laminated. Further, the first electrode C1 may be electrically connected to the first gate electrode G1 through the contact hole.

The second electrode C2 may be disposed so as to overlap the first electrode C1. The second electrode C2 may be formed by electrically connecting a light shielding layer disposed on the bottom of the non-emission area NEA and a metal layer disposed on the same layer as the first gate electrode G1 to the first source electrode S1 and the third source electrode S3 through the contact hole.

In summary, the first electrode C1 of the storage capacitor SC is a conductive area of the second active layer A2 in which the semiconductor layer and the transparent oxide layer are laminated. The first electrode C1 may be electrically connected to the first gate electrode G1 of the driving transistor DT and the second source electrode S2 of the switching transistor SWT through the contact hole. Further, in the second electrode C2, a light shielding layer and a metal layer disposed on the same layer as the first gate electrode 121 may be electrically connected to the first source electrode S1 of the driving transistor DT and the third source electrode S3 of the sensing transistor SET through the contact hole.

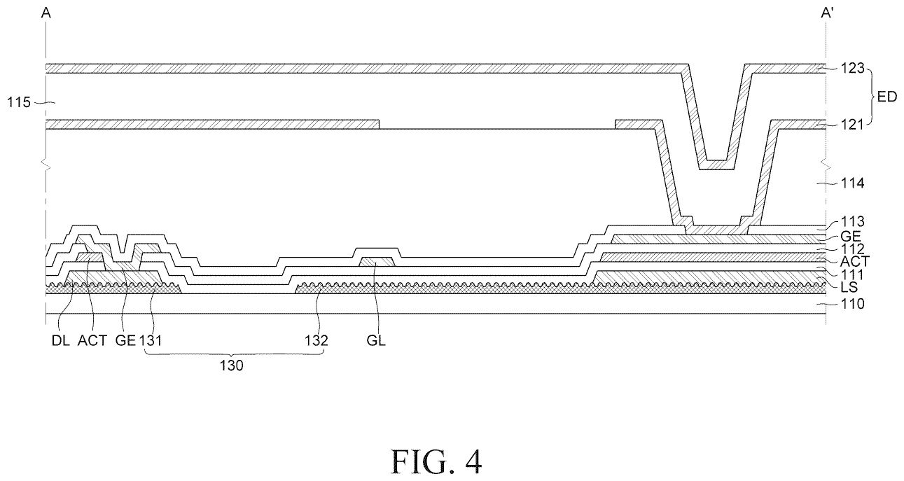

Referring to FIGS. 3 and 4, the display device 100 according to the exemplary embodiment of the present disclosure further includes a transmission reduction layer 130.

The transmission reduction layer 130 may be disposed so as to overlap wiring lines and a driving circuit disposed in the pixel PX. The transmission reduction layer 130 may be disposed below a wiring line which is disposed on the bottom, among wiring lines disposed in the pixel PX. The transmission reduction layer 130 may be disposed below a configuration which is disposed on the bottom, among configurations disposed in the driving circuit.

The transmission reduction layer 130 may be formed of a conductive material. The transmission reduction layer 130 may be formed of a transparent oxide layer. The transmission reduction layer 130 may have an uneven surface. For example, the transmission reduction layer 130 may be formed of a transparent oxide layer formed of indium tin oxide (ITO) and is subject to H2 plasma treatment to form an uneven shape on the surface and is blackened to lower a transmittance.

The transmission reduction layer 130 may include a first transmission reduction layer 131 and a second transmission reduction layer 132.

For example, the first transmission reduction layer 131 may be disposed so as to overlap the high potential power line VDDL, the plurality of data lines DL, and the reference line RL. For example, the first transmission reduction layer 131 may be disposed below the high potential power line VDDL, the plurality of data lines DL, and the reference line RL.

Further, the second transmission reduction layer 132 may be disposed below the switching transistor SWT, the sensing transistor SET, the driving transistor DT, and the storage capacitor SC disposed in the non-emission area NEA.

FIG. 4 is a cross-sectional view taken along A-A′ of FIG. 3 according to one embodiment. In FIG. 4, for the convenience of description, only from the substrate 110 to the cathode 123 of the light emitting diode ED are illustrated.

Referring to FIG. 4, the display device 100 according to the exemplary embodiment of the present disclosure includes a substrate 110, a light shielding layer LS, a buffer layer 111, a gate insulating layer 112, a passivation layer 113, an over coating layer 114, a light emitting diode ED, and a bank layer 115.

The substrate 110 supports various components of the display device 100. The substrate 110 may be formed of an insulating material. For example, the substrate 110 may be formed of glass and may be formed of a plastic material, such as polyimide (PI).

The metal layer may be disposed on the substrate 110. The metal layer may be the high potential power line VDDL, the plurality of data lines DL, the reference line RL, and the gate line GL. However, in FIG. 4, for the convenience of description, the data line DL and the gate line GL are illustrated.

Further, the metal layer may be a light shielding layer LS which is disposed in an overlapping area below the switching transistor SWT, the sensing transistor SET, the driving transistor DT, and the storage capacitor SC which configure the driving circuit. The light shielding layer LS overlaps the channel regions of the switching transistor SWT, the sensing transistor SET, and the driving transistor DT to serve as a light shield.

The transmission reduction layer 130 may be disposed on the substrate 110. In one embodiment, the transmission reduction layer 130 is directly on the substrate 110 such that the transmission reduction layer 130 contacts the substrate 110. For example, a lower surface of the transmission reduction layer 130 is in direct contact with an upper surface of the substrate 110.

The transmission reduction layer 130 may be disposed between the substrate 110 and the metal layer. The transmission reduction layer 130 may be disposed so as to be in contact with a top surface of the substrate 110. The transmission reduction layer 130 may be disposed so as to be in contact with a bottom surface of some metal layers. For example, the transmission reduction layer 130 may be disposed so as to be in contact with bottom layers of the data line DL and the light shielding layer LS. For example, a first transmission reduction layer 131 may be disposed so as to be in contact with a bottom layer of the data line DL. For example, a second transmission reduction layer 132 is disposed so as to be in contact with a bottom surface of the light shielding layer LS and may extend toward the gate line GL. For example, the second transmission reduction layer 132 may be disposed to extend over an area overlapping the gate line GL below the gate line GL on a bottom surface of the light shielding layer LS.

A surface treatment layer may be disposed on a surface of the transmission reduction layer 130. The surface treatment layer may have an uneven shape obtained by performing a plasma treatment on a surface of the transmission reduction layer 130 to be blackened. For example, the transmission reduction layer 130 may have an uneven shape obtained by performing a plasma treatment on an upper surface to be blackened. For example, if the H2 plasma treatment is performed after placing a transparent oxide layer formed of an ITO material on the substrate 110, indium precipitation occurs due to hydrogen radical reaction with indium oxide so that the roughness of the transmission reduction layer 130 is increased and is blackened. Thus, the upper surface (e.g., a first surface) of the transmission reduction layer 130 is less smooth than a lower surface (e.g., a second surface) of the transmission reduction layer 130 due to the plasma treatment. Furthermore, the upper surface of the transmission reduction layer 130 is less transmissive of external light than the lower surface of the transmission reduction layer 130 due to the plasma treatment blackening the upper surface, for example.

A buffer layer 111 is disposed on the substrate 110. For example, the buffer layer 111 may be disposed on the substrate 110 so as to cover the light shielding layer LS and the transmission reduction layer 130. The buffer layer 111 is a layer for protecting the driving transistor DT from impurities such as alkali ions leaked from the substrate 110 or layers therebelow. The buffer layer 111 may be formed of silicon oxide SiOx, silicon nitride SiNx, or a double layer thereof.

The active layer ACT may be disposed on the buffer layer 111.

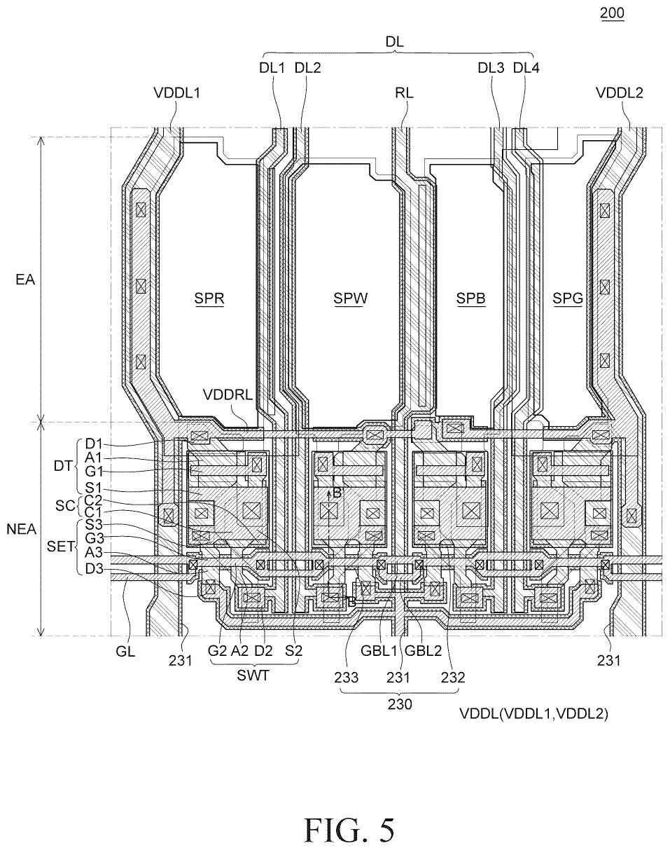

The active layer ACT may be the same layer as the first active layer A1 of the driving transistor DT, the second active layer A2 of the switching transistor SWT, and the third active layer A3 of the sensing transistor SET. For example, referring to FIG. 5, the active layer ACT disposed on the data line DL may be a second source electrode S2 of the switching transistor SWT which is electrically connected to the data line DL. For example, the active layer ACT disposed on the light shielding layer LS may be a first active layer A1 which is connected to the first gate electrode G1 of the driving transistor DT.

The active layer ACT may be formed of amorphous silicon (a-Si), polycrystalline silicon (poly-Si), an oxide semiconductor, or an organic semiconductor. When the active layer ACT is formed by oxide semiconductor, the active layer may be formed as a single layer of indium gallium zinc oxide (IGZO) or a double layer of indium gallium zinc oxide (IGZO) and molybdenum alloy (MoTi), but is not limited thereto.

The gate insulating layer 112 is disposed on the active layer ACT. The gate insulating layer 112 may insulate a gate electrode which overlaps the active layer ACT. The gate insulating layer 112 may be formed as a single layer of silicon nitride (SiNx) or silicon oxide (SiOx) which is an inorganic material or a multiple layer of silicon nitride (SiNx) and silicon oxide (SiOx), but it is not limited thereto.

The gate electrode layer GE is disposed on the gate insulating layer 112. The gate electrode layer GE may be formed of a conductive material such as titanium (Ti), copper (Cu), aluminum (Al), molybdenum (Mo), or an alloy thereof, but is not limited thereto. For example, referring to FIG. 5, the gate electrode layer GE may be a connection electrode which is electrically connected to the data line DL through contact holes formed in the buffer layer 111 and the gate insulating layer 112 or a gate line GL which transmits a scan signal SCAN and a sensing signal SENSE. Further, the gate electrode layer GE may be a connection electrode which is connected to the anode 121 of the light emitting diode ED and the first source electrode S1 of the driving transistor DT.

The passivation layer 113 may be conformally disposed on the gate electrode layer GE. For example, the passivation layer 113 may be formed along a shape of a top surface of the gate electrode layer GE. Further, the passivation layer 113 is formed to cover the gate electrode GE and is also disposed on the front surface of the substrate 110. The passivation layer 113 may protect the driving circuit from oxygen or moisture from the outside of the display device 100. Various organic films or inorganic films may be used for the passivation layer 113. The passivation layer 113 may be formed by various structures, such as a single deposition structure of an organic film, a single deposition structure of an inorganic film, or an alternative deposition structure of organic film/inorganic film. For example, the passivation layer 113 may be formed of silicon nitride (SiNx) or silicon oxide (SiOx), but is not limited thereto.

The over coating layer 114 may be disposed on the passivation layer 113.

The over coating layer 114 is an insulating layer which planarizes an upper portion of the passivation layer 113. The over coating layer 114 may be formed of an organic material. For example, the over coating layer 114 may be formed of one of acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The light emitting diode ED is disposed on the over coating layer 114. The light emitting diode ED includes an anode 121, an emission layer, and a cathode 123.

The anode 121 may be disposed on the over coating layer 114 so as to correspond an emission area EA of each pixel PX. The anode 121 may be electrically connected to the gate electrode layer GE through a contact hole of the over coating layer 114. For example, the anode 121 may be electrically connected to the gate electrode layer GE which is electrically connected to the first source electrode S1 of the driving transistor DT. The anode 121 may be formed of a conductive material. For example, the anode 121 may be configured by a transparent conductive material, such as tin oxide (TO), indium tin oxide (ITO), indium zinc oxide (IZO), or indium tin zinc oxide (ITZO), but is not limited thereto.

A bank layer 115 may be disposed on the anode 121 and the over coating layer 114. The bank layer 115 covers an end of the anode 121 to define the emission area EA. Therefore, the bank layer 115 may expose the anode 121 corresponding to the emission area. The bank layer 115 is disposed at the boundary between the sub pixels SP which are adjacent to each other to reduce the color mixture of light emitted from the light emitting diode ED of each of the plurality of sub pixels SP.

The bank layer 115 may be formed of a black material. The bank layer 115 includes the black material to block metal layers which may be visible through the active area AA. For example, the bank layer 115 may be formed of a carbon-based mixture and for example, include a carbon black, but is not limited thereto.

The emission layer may be disposed on the anode 121 exposed by the bank layer 115. The emission layer may include a hole injection layer, a hole transport layer, a light emitting layer, an electron transport layer, and an electron injection layer.

The cathode 123 may be disposed on the emission layer. The cathode 123 supplies electrons to the emission layer 142 so that the cathode may be formed of a conductive material having a low work function. The cathode 123 may be formed as one layer over the plurality of sub pixels SP. That is, the cathodes 123 of the plurality of sub pixels SP are connected to be integrally formed.

In the case of the display device according to the related art, the reflection of the external light is severe due to configurations which configure the wiring line and the driving circuit.

Accordingly, in the display device 100 according to the exemplary embodiment of the present disclosure, the transmission reduction layer 130 is disposed between the metal layer which is disposed to be the closer to the substrate 110 than other metal layers of the display device 100 and the substrate 110 to minimize the reflection of external light. Specifically, the transmission reduction layer 130 is disposed so as to overlap bottoms of the high potential power line VDDL, the plurality of data lines DL, the reference line RL, and the gate line GL which are metal layers disposed to be the closer to the substrate 110 than the different metal layers in the display device 100 and the switching transistor SWT, the sensing transistor SET, the driving transistor DT, and the storage capacitor SC which configure the driving circuit.

In the following Table 1, an experiment result of a reflection reduction rate of the display device is represented.

TABLE 1

| | Line | | | Area | | Reflection |
|---|---|---|---|---|---|---|
| | reflection | Shielding | Exposed | shield | | reduction |
| Category | area | area | area | rate | Transmittance | rate |
| Comp. Ex. | 43,843 | 0 | 43,843 | 0% | 100% | 0% |
| Ex. | 43,843 | 39,307 | 4,536 | 89.7% | 60% | 57.4% |

Here, the area may be μm\hat{ }2.

In Table 1, Comparative Example relates to a display device of the related art and Example relates to a display device according to an exemplary embodiment of the present disclosure.

Referring to Table 1, in the case of the display device 100 according to the exemplary embodiment of the present disclosure, the transmission reduction layer 130 is disposed below the metal layer which is disposed to be the closest to the substrate 110 amongst the metal layers in the display device 100 and overlaps the metal layer to reduce an area exposed to the external light as compared with the display device of the related art. Further, the transmittance is reduced to reduce both a transmittance to incident external light and transmittance of light which is reflected by the metal layer to be discharged to the outside so that the reduction rate of the external reflection may be improved and the reflection of the external light may be minimized.

The display device 100 according to the exemplary embodiment of the present disclosure may improve optical reliability and thermal stability of the transistor. Specifically, in the display device 100 according to the exemplary embodiment of the present disclosure, the transmission reduction layer 130 is disposed so as to overlap bottoms of the light shielding layers of the switching transistor SWT, the sensing transistor SET, and the driving transistor DT which configure the driving circuit which is a metal layer disposed to be the closest to the substrate 110 amongst metal layers of the display device 100. Accordingly, in the display device 100 according to the exemplary embodiment of the present disclosure, the transmission reduction layer 130 is disposed below the light shielding layer LS of the switching transistor SWT, the sensing transistor SET, and the driving transistor DT to minimize or at least reduce the transmission of ultraviolet light, among external light. Therefore, optical reliability and thermal stability of the transistor according to the external light may be improved.

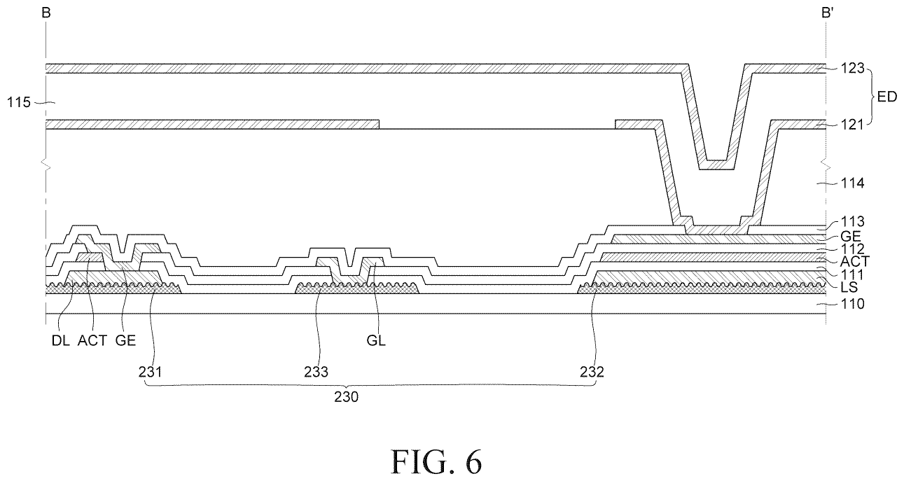

FIG. 5 is a plan view of a display device according to another exemplary embodiment of the present disclosure. FIG. 6 is a cross-sectional view for B-B′ of FIG. 5 according to an exemplary embodiment of the present disclosure. In FIGS. 5 and 6, a configuration excluding a transmission reduction layer 230 is the same as FIGS. 3 and 4 so that a detailed description will be omitted.

Referring to FIG. 5, the display device 200 according to another exemplary embodiment of the present disclosure includes a transmission reduction layer 230.

The transmission reduction layer 230 may be disposed so as to overlap wiring lines and a driving circuit disposed in the pixel PX. The transmission reduction layer 230 may be disposed below a wiring line which is disposed on the bottom amongst wiring lines disposed in the pixel PX. The transmission reduction layer 230 may be disposed below a configuration which is disposed on the bottom, among configurations disposed in the driving circuit.

The transmission reduction layer 230 may be formed of a conductive material. The transmission reduction layer 230 may be formed of a transparent oxide layer. The transmission reduction layer 230 has an uneven surface. For example, the transmission reduction layer 230 may be formed of a transparent oxide layer formed of indium tin oxide (ITO) and is subject to H2 plasma treatment to form an uneven shape on the surface and is blackened to lower a transmittance.

The transmission reduction layer 230 may include a first transmission reduction layer 231, a second transmission reduction layer 232, and a third transmission reduction layer 233. The first transmission reduction layer 231, the second transmission reduction layer 232, and the third transmission reduction layer 233 are disposed on a same layer and are spaced apart from each other.

For example, the first transmission reduction layer 231 may be disposed so as to overlap the high potential power line VDDL, the plurality of data lines DL, and the reference line RL. For example, the first transmission reduction layer 231 may be disposed below the high potential power line VDDL, the plurality of data lines DL, and the reference line RL.

For example, the second transmission reduction layer 232 may be disposed below the switching transistor SWT, the sensing transistor SET, the driving transistor DT, and the storage capacitor SC disposed in the non-emission area NEA. For example, the second transmission reduction layer 232 may be disposed so as to overlap the switching transistor SWT, the sensing transistor SET, the driving transistor DT, and the storage capacitor SC.

For example, the third transmission reduction layer 233 may be disposed below the gate line GL disposed in the first direction. For example, the third transmission reduction layer 233 may be disposed so as to overlap the gate line GL.

In FIG. 6, for the convenience of description, from the substrate 110 to the cathode 123 of the light emitting diode ED are illustrated.

Referring to FIG. 6, the transmission reduction layer 230 may be disposed on the substrate 110.

The transmission reduction layer 230 may be disposed between the substrate 110 and the metal layer.

The transmission reduction layer 230 may be disposed so as to be in contact with a top surface of the substrate 110. The transmission reduction layer 230 may be disposed so as to be in contact with a bottom surface of some metal layers.

For example, the transmission reduction layer 230 may be disposed so as to be in contact with bottom layers of the data line DL and the light shielding layer LS. For example, a first transmission reduction layer 231 may be disposed so as to be in contact with a bottom layer of the data line DL. For example, the second transmission reduction layer 232 may be disposed so as to be in contact with a bottom layer of the light shielding layer LS.

The third transmission reduction layer 233 may be disposed below the gate line GL so as to overlap the gate line GL. The third transmission reduction layer 233 may be electrically connected to the gate line GL through contact holes formed in the buffer layer 111 and the gate insulating layer 112.

Accordingly, in the display device 200 according to another exemplary embodiment of the present disclosure, the transmission reduction layer 230 is disposed between the metal layer which is disposed to be the closer to the substrate 110 than other metal layers in the display device 200 and the substrate 110 to minimize or at least reduce the reflection of external light. Specifically, the transmission reduction layer 230 is disposed so as to overlap bottoms of the high potential power line VDDL, the plurality of data lines DL, the reference line RL, and the gate line GL which are metal layers disposed closer to the substrate 110 than other metal layers of the display device 200 and the switching transistor SWT, the sensing transistor SET, the driving transistor DT, and the storage capacitor SC which configure the driving circuit. Accordingly, in the display device 200 according to another exemplary embodiment of the present disclosure, the transmission reduction layer 230 is disposed below the metal layer which is disposed closer to the substrate 110 than other metal layers of the display device 200 to overlap the metal layer to reduce an area exposed to the external light as compared with the display device of the related art. Further, the transmittance is reduced to reduce both a transmittance to incident external light and transmittance of light which is reflected by the metal layer to be discharged to the outside so that the reduction rate of the external reflection may be improved and the reflection of the external light may be minimized.

Specifically, in the display device 200 according to another exemplary embodiment of the present disclosure, the transmission reduction layer 230 is disposed so as to overlap bottoms of the light shielding layers of the switching transistor SWT, the sensing transistor SET, and the driving transistor DT which configure the driving circuit which is a metal layer disposed closer to the substrate 110 than other metal layers of the display device 200. Accordingly, in the display device 200 according to another exemplary embodiment of the present disclosure, the transmission reduction layer 230 is disposed below the light shielding layer LS of the switching transistor SWT, the sensing transistor SET, and the driving transistor DT to minimize the transmission of ultraviolet light, among external light. Therefore, optical reliability and thermal stability of the transistor according to the external light may be improved.

The display device 200 according to another exemplary embodiment of the present disclosure may reduce a line load. Specifically, the transmission reduction layer 230 is disposed below the gate line GL which transmits a gate signal, among the metal layers which are disposed so as to be the closest to the substrate 110, to overlap the gate line GL and to be electrically connected to the gate line GL. Accordingly, in the display device 200 according to another exemplary embodiment of the present disclosure, the transmission reduction layer 230 is disposed below the gate line GL to be electrically connected to the gate line GL to reduce resistance of the gate line GL and reduce a line load.

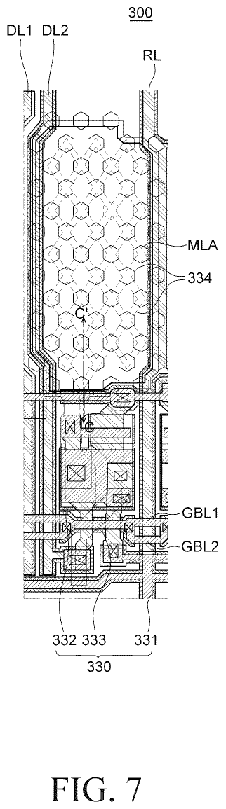

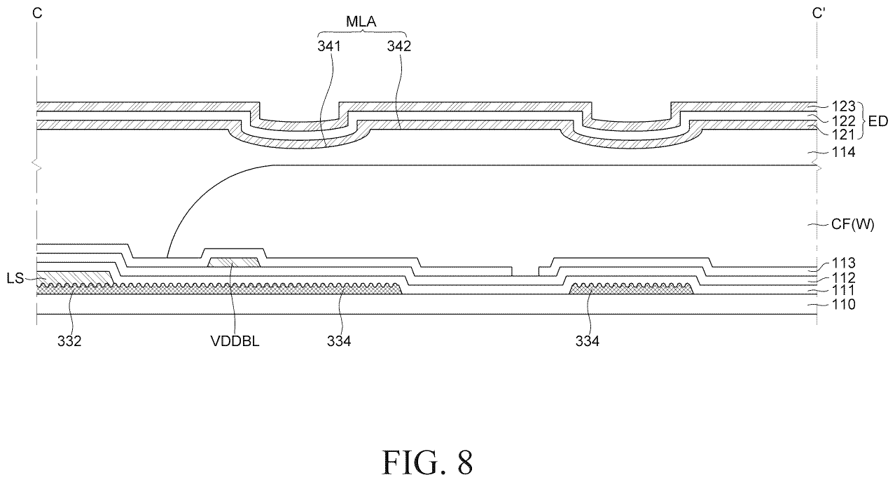

FIG. 7 is a plan view of a display device according to still another exemplary embodiment of the present disclosure. FIG. 8 is a cross-sectional view for C-C′ of FIG. 7 according to an exemplary embodiment of the present disclosure. In FIG. 7, a white sub pixel SPW is illustrated for the convenience of description. In FIGS. 7 and 8, a configuration excluding a plurality of micro lenses MLA and a transmission reduction layer 330 is the same as FIGS. 5 and 6 so that a redundant description will be omitted.

Referring to FIGS. 7 and 8, the display device 300 according to still another exemplary embodiment of the present disclosure includes a plurality of micro lenses MLA.

The plurality of micro lenses MLA may be configured by a plurality of concave portions 341 disposed on the over coating layer 114 that are concave in a direction toward the substrate 110 and a connection portion 342 that connects together the plurality of concave portions 341.

The plurality of concave portions 341 may be disposed so as to overlap a color filter layer CF. The plurality of concave portions 341 may have a hemispherical shape or a semi-ellipsoidal shape. The over coating layer 114 provides a flat top surface in a portion in which the plurality of concave portions 341 is not formed. That is, a portion of the over coating layer 114 that is disposed between a pair of concave portions 341 is substantially flat compared to the concave portions 341.

The connection portion 342 may be a flat surface on the over coating layer 114 in which the plurality of concave portions 341 is connected to each other.

The plurality of micro lenses MLA extracts light trapped in the display device 300 to the outside to increase an emission efficiency of the display device 300. For example, light emitted from the emission layer may be totally reflected from an interface between the anode 121 and the over coating layer 114. Accordingly, an incident angle of light which is incident to the interface of the over coating layer 114 is highly likely to be smaller than a critical angle of the total reflection to reduce an amount of light trapped in the display device 300.

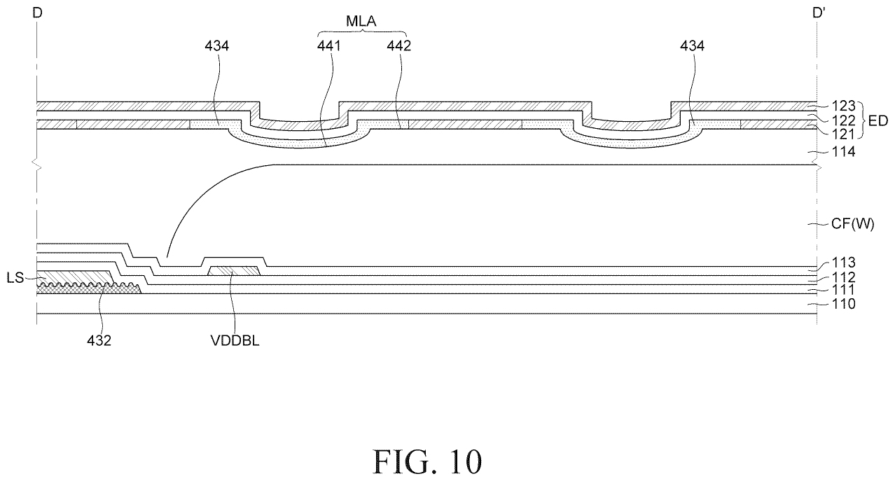

When a plurality of micro lenses MLA including a plurality of concave portions 341 are formed on the over coating layer 114 by a process, such as photolithography, in the over coating layer 114, a peaky portion with a rapid change in morphology, that is, a connection portion 342 is provided between the plurality of concave portions 341. However, the emission layer of the light emitting layer ED is formed by a method which does not provide a good step coverage of the emission layer, such as a thermal deposition method and the emission layer is formed with a very thin thickness of several hundred nm. Accordingly, on the anode 121, there may be an area in which the emission layer is not formed so that there is a high probability that the short-circuit is formed between the anode 121 and the cathode 123. Therefore, even though it is not illustrated in FIG. 10, an insulating layer may be further disposed between the anode 121 and the over coating layer 114 to relieve a step which may be generated by the plurality of concave portion 341.

In the meantime, the sub pixel SP of the display device 300 according to still another exemplary embodiment of the present disclosure may have a color-filter on transistor (COT) structure. For example, colors of the sub pixels SP may be implemented by a color filter layer CF disposed so as to overlap the emission area EA of the sub pixel SP. For example, the color filter layer CF may include a red color filter, a green color filter, and a blue color filter which are separated so as to correspond to each of the red sub pixel SPR, the white sub pixel SPW, the blue sub pixel SPB, and the green sub pixel SPG and are located on the same plane. For example, when the light emitting diode ED emits white light, a red color filter layer is disposed in an area corresponding to the emission area of the light emitting diode ED to implement a red sub pixel SPR and a green color filter layer is disposed in an area corresponding to the emission area of the light emitting diode ED to implement a green sub pixel SPG. Further, a blue color filter layer is disposed in an area corresponding to the emission area of the light emitting diode ED to implement a blue sub pixel SPB and a transparent color filter layer which does not include a color pigment is disposed in an area corresponding to the emission area of the light emitting diode ED to implement a white sub pixel SPW. However, the present disclosure is not limited thereto and the color filter layer CF may not be disposed in the white sub pixel SPW.

The color filter layer CF may be disposed on the passivation layer 113 so as to overlap the emission area EA of the sub pixel SP. For example, the color filter layer CF is formed so as to overlap the emission area EA. The formation position and a size of the color filter layer CF may be determined by various factors, such as a distance between the color filter layer CF and the anode 121, a distance between the color filter layer CF and the over coating layer 114, and a distance between the emission areas, as well as a size and a position of the emission area.

Referring to FIGS. 7 and 8, the display device 300 according to still another exemplary embodiment of the present disclosure includes a transmission reduction layer 330.

The transmission reduction layer 330 may be disposed so as to overlap wiring lines and a driving circuit disposed in the pixel PX. The transmission reduction layer 330 may be disposed below a wiring line which is disposed on the bottom, among wiring lines disposed in the pixel PX. The transmission reduction layer 330 may be disposed below a configuration which is disposed on the bottom, among configurations which configure the driving circuit.

The transmission reduction layer 330 may be formed of a conductive material. The transmission reduction layer 330 may be formed of a transparent oxide layer. The transmission reduction layer 330 may have an uneven surface. For example, the transmission reduction layer 330 may be formed of a transparent oxide layer formed of indium tin oxide (ITO) and is subject to H2 plasma treatment to form an uneven shape on the surface and is blackened to lower a transmittance.

The transmission reduction layer 330 may include a first transmission reduction layer 331, a second transmission reduction layer 332, a third transmission reduction layer 333, and a fourth transmission reduction layer 334.

The first transmission reduction layer 331 may be disposed so as to overlap the high potential power line VDDL, the plurality of data lines DL, and the reference line RL. For example, the first transmission reduction layer 331 may be disposed below the high potential power line VDDL, the plurality of data lines DL, and the reference line RL.

The second transmission reduction layer 332 may be disposed below the switching transistor SWT, the sensing transistor SET, the driving transistor DT, and the storage capacitor SC disposed in the non-emission area NEA. For example, the second transmission reduction layer 332 may be disposed so as to overlap the switching transistor SWT, the sensing transistor SET, the driving transistor DT, and the storage capacitor SC.

The third transmission reduction layer 333 may be disposed below the gate line GL disposed in the first direction. For example, the third transmission reduction layer 333 may be disposed so as to overlap the gate line GL. The third transmission reduction layer 333 may be electrically connected to a gate line GL. For example, the third transmission reduction layer 333 may be electrically connected to the gate line GL through contact holes formed in the buffer layer 111 and the gate insulating layer 112.

The fourth transmission reduction layer 334 may be disposed below the plurality of concave portions 341. The fourth transmission reduction layers 334 may be connected to each other. For example, the fourth transmission reduction layer 334 may be disposed so as to overlap the plurality of concave portions 341 and is disposed so as to overlap the connection portion 342 between adjacent concave portions 341, among the plurality of concave portions 341 to be connected to each other. The fourth transmission reduction layer 334 may be electrically connected to the second transmission reduction layer 332. If the fourth transmission reduction 334 is spaced apart from the first transmission reduction 331, the second transmission reduction 332, and the third transmission reduction 333 to be floated, the signal interference due to a capacitance with other wiring line or electrodes which overlap the fourth transmission reduction layer 334 may occur. Therefore, in order to reduce the interference with other signals, the fourth transmission reduction layer 334 may be electrically connected to the second transmission reduction layer 332.

Accordingly, in the display device 300 according to still another exemplary embodiment of the present disclosure, the transmission reduction layer 330 is disposed between the metal layer which is disposed closer to the substrate 110 than other metal layers of the display device 300 and the substrate 110 to minimize or at least reduce the reflection of external light. Specifically, the transmission reduction layer 330 is disposed so as to overlap bottoms of the high potential power line VDDL, the plurality of data lines DL, the reference line RL, and the gate line GL which are metal layers disposed to be the closest to the substrate 110 amongst the other metal layers and the switching transistor SWT, the sensing transistor SET, the driving transistor DT, and the storage capacitor SC which configure the driving circuit. Accordingly, in the display device 300 according to still another exemplary embodiment of the present disclosure, the transmission reduction layer 330 is disposed below the metal layer which is disposed to be the closest to the substrate 110 amongst the metal layers of the display device 300 to overlap the metal layer and reduce an area exposed to the external light as compared with the display device of the related art. Further, the transmittance is reduced to reduce both a transmittance to incident external light and transmittance of light which is reflected by the metal layer to be discharged to the outside so that the reduction rate of the external reflection may be improved and the reflection of the external light may be minimized.

In the display device 300 according to still another exemplary embodiment of the present disclosure, the transmission reduction layer 330 is disposed so as to overlap bottoms of the light shielding layers of the switching transistor SWT, the sensing transistor SET, and the driving transistor DT which configure the driving circuit which is a metal layer disposed closer to the substrate 110 than other metal layers of the display device 300. Accordingly, in the display device 300 according to still another exemplary embodiment of the present disclosure, the transmission reduction layer 330 is disposed below the light shielding layer LS of the switching transistor SWT, the sensing transistor SET, and the driving transistor DT to minimize or at least reduce the transmission of ultraviolet light, among external light. Therefore, optical reliability and thermal stability of the transistor according to the external light may be improved.

The display device 300 according to still another exemplary embodiment of the present disclosure may reduce a line load. Specifically, the transmission reduction layer 330 is disposed below the gate line GL which transmits a gate signal, among the metal layers which are disposed so as to be the closest to the substrate 110, to overlap the gate line GL and to be electrically connected to the gate line GL. Accordingly, in the display device 300 according to still another exemplary embodiment of the present disclosure, the transmission reduction layer 330 is disposed below the gate line GL to be electrically connected to the gate line GL to reduce resistance of the gate line GL and reduce a line load.

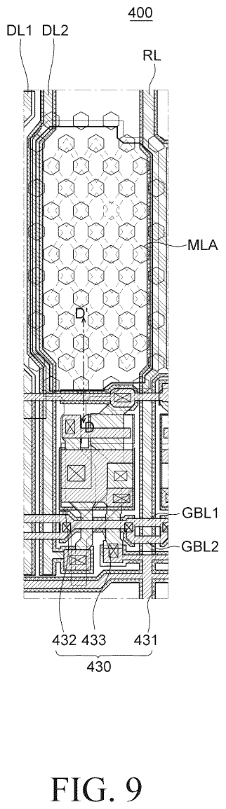

FIG. 9 is a plan view of a display device according to still another exemplary embodiment of the present disclosure. FIG. 10 is a cross-sectional view for D-D′ of FIG. 9 according to another embodiment of the present disclosure. In FIG. 10, a white sub pixel SPW is illustrated for the convenience of description. In FIGS. 9 and 10, a configuration excluding a transmission reduction layer 430 is the same as FIGS. 7 and 8 so that a detailed description will be omitted.

Referring to FIGS. 9 and 10, a display device 400 according to still another exemplary embodiment of the present disclosure further includes a transmission reduction layer 430 and a lens transmission reduction layer 434.

The transmission reduction layer 430 may be disposed so as to overlap wiring lines and a driving circuit disposed in the pixel PX. The transmission reduction layer 430 may be disposed below a wiring line which is disposed on the bottom, among wiring lines disposed in the pixel PX. The transmission reduction layer 430 may be disposed below a configuration which is disposed on the bottom, among configurations disposed in the driving circuit.

The transmission reduction layer 430 may be formed of a conductive material. The transmission reduction layer 430 may be formed of a transparent oxide layer. The transmission reduction layer 430 has an uneven surface. For example, the transmission reduction layer 430 is formed of a transparent oxide layer formed of indium tin oxide (ITO) and is subject to H2 plasma treatment to form an uneven shape on the surface and is blackened to lower a transmittance.

The transmission reduction layer 430 may include a first transmission reduction layer 431, a second transmission reduction layer 432, and a third transmission reduction layer 433.

The first transmission reduction layer 431 may be disposed so as to overlap the high potential power line VDDL, the plurality of data lines DL, and the reference line RL. For example, the first transmission reduction layer 431 may be disposed below the high potential power line VDDL, the plurality of data lines DL, and the reference line RL.

The second transmission reduction layer 432 may be disposed below the switching transistor SWT, the sensing transistor SET, the driving transistor DT, and the storage capacitor SC disposed in the non-emission area NEA. For example, the second transmission reduction layer 432 may be disposed so as to overlap the switching transistor SWT, the sensing transistor SET, the driving transistor DT, and the storage capacitor SC.

The third transmission reduction layer 433 may be disposed below the gate line GL disposed in the first direction. For example, the third transmission reduction layer 433 may be disposed so as to overlap the gate line GL. The third transmission reduction layer 433 may be electrically connected to a gate line GL. For example, the third transmission reduction layer 433 may be electrically connected to the gate line GL through contact holes formed in the buffer layer 111 and the gate insulating layer 112.

The lens transmission reduction layer 434 may be disposed below the plurality of concave portions 441. The lens transmission reduction layer 434 may be disposed below a connection portion 442 between adjacent concave portions 441, among the plurality of concave portions 341. For example, the lens transmission reduction layer 434 may be disposed so as to overlap the plurality of concave portions 441 and may be disposed so as to overlap the connection portion 442 between adjacent concave portions 441, among the plurality of concave portions 441. The lens transmission reduction layer 434 may be disposed on the same layer as the anode 121 of the light emitting diode ED. For example, the lens transmission reduction layer 434 may be a part of the anode 121 disposed in an area overlapping the plurality of concave portions 441 and the connection portion 442. The lens transmission reduction layer 434 may be formed of a conductive material. The lens transmission reduction layer 434 may be formed of a transparent oxide layer. The lens transmission reduction layer 434 has an uneven surface. For example, the lens transmission reduction layer 434 is formed by placing an anode 121 formed of a transparent oxide layer formed of indium tin oxide (ITO) on the over coating layer 114 and then performing H2 plasma treatment on a surface of a partial area overlapping the plurality of concave portions 341 and the connection portion 342 to form an uneven shape and being blackened.

Accordingly, in the display device 400 according to another exemplary embodiment of the present disclosure, the transmission reduction layer 430 is disposed between the metal layer which is closer to the substrate 110 than other metal layers of the display device 400 and the substrate 110 and the lens transmission reduction layer 434 is disposed on the same layer as the anode 121. Therefore, the reflection of external light may be minimized or at least reduced. Specifically, the transmission reduction layer 430 is disposed so as to overlap bottoms of the high potential power line VDDL, the plurality of data lines DL, the reference line RL, and the gate line GL which are metal layers disposed to be the closest to the substrate 110 and the switching transistor SWT, the sensing transistor SET, the driving transistor DT, and the storage capacitor SC which configure the driving circuit. Further, the lens transmission reduction layer 434 is disposed on the over coating layer 114 so as to overlap the plurality of concave portions 341 and the connection portion 342. The lens transmission reduction layer 434 is disposed on the same layer as the anode 121 and is disposed in a partial area of the anode 121 which overlaps the plurality of concave portions 341 and the connection portion 342. Accordingly, in the display device 400 according to still another exemplary embodiment of the present disclosure, the transmission reduction layer 430 is disposed below the metal layer which is disposed to be the closest to the substrate 110 to overlap the metal layer and the lens transmission reduction layer 434 is disposed so as to overlap the micro lens MLA. Therefore, an area exposed to the external light is reduced as compared with the display device of the related art and the transmittance is reduced to reduce both a transmittance to incident external light and transmittance of light which is reflected by the metal layer to be discharged to the outside so that the reduction rate of the external reflection is improved and the reflection of the external light may be minimized.

Specifically, in the display device 400 according to still another exemplary embodiment of the present disclosure, the transmission reduction layer 430 is disposed so as to overlap bottoms of the light shielding layers of the switching transistor SWT, the sensing transistor SET, and the driving transistor DT which configure the driving circuit which is a metal layer disposed to be the closest to the substrate 110. Accordingly, in the display device 400 according to still another exemplary embodiment of the present disclosure, the transmission reduction layer 430 is disposed below the light shielding layer LS of the switching transistor SWT, the sensing transistor SET, and the driving transistor DT to minimize the transmission of ultraviolet light, among external light. Therefore, optical reliability and thermal stability of the transistor according to the external light may be improved.

The display device 400 according to still another exemplary embodiment of the present disclosure may reduce a line load. Specifically, the transmission reduction layer 430 is disposed below the gate line GL which transmits a gate signal, among the metal layers which are disposed so as to be the closest to the substrate 110, to overlap the gate line GL and to be electrically connected to the gate line GL. Accordingly, in the display device 400 according to still another exemplary embodiment of the present disclosure, the transmission reduction layer 430 is disposed below the gate line GL to be electrically connected to the gate line GL to reduce resistance of the gate line GL and reduce a line load.

The exemplary embodiments of the present disclosure can also be described as follows:

In one embodiment, a display device comprises: a substrate; a plurality of sub pixels on the substrate, each of the plurality of sub pixels including an emission area and a non-emission area; a metal layer on the substrate, the metal layer closer to the substrate than other metal layers of the display device; and a transmission reduction layer that reduces transmission of external light, the transmission reduction layer between the metal layer and the substrate and having a first surface that is black and less smooth than a second surface of the transmission reduction layer.

In one embodiment, the transmission reduction layer includes a conductive material.

In one embodiment, the metal layer includes a plurality of wiring lines on the substrate and the transmission reduction layer overlaps the plurality of wiring lines.

In one embodiment, the plurality of sub pixels includes a plurality of transistors on the substrate, the metal layer is between the plurality of transistors and the substrate such that the metal layer overlaps the plurality of transistors, and the transmission reduction layer overlaps the metal layer and the plurality of transistors.

In one embodiment, the metal layer further includes a gate line on the substrate and the transmission reduction layer that overlaps the plurality of transistors also overlaps the gate line.

In one embodiment, the metal layer further includes agate line on the substrate and another transmission reduction layer overlaps the gate line such that the other transmission reduction layer is spaced apart from the transmission reduction layer that overlaps the plurality of wiring lines.

In one embodiment, the other transmission reduction layer that overlaps the gate line is electrically connected to the gate line.

In one embodiment, the display device further comprises an over coating layer on the substrate, the over coating layer including a plurality of micro lenses on the emission area of at least one of the plurality of sub pixels.

In one embodiment, the transmission reduction layer overlaps the plurality of micro lenses.

In one embodiment, the transmission reduction layer that overlaps the plurality of micro lenses is connected to another transmission reduction layer.

In one embodiment, the metal layer further includes a gate line on the substrate, and the other transmission reduction layer overlaps the gate line and is electrically connected to the transmission reduction layer that overlaps the plurality of micro lenses.

In one embodiment, the display device further comprises a lens transmission reduction layer on the over coating layer, the lens transmission reduction layer overlapping the plurality of micro lenses.

In one embodiment, the display device further comprises a plurality of light emitting diodes on the substrate, each of the plurality of light emitting diodes including an anode, an emission layer on the anode, and a cathode on the emission layer, wherein the lens transmission reduction layer is on a same layer as the anode.

In one embodiment, a display device comprises: a substrate; a plurality of sub pixels on the substrate, each of the plurality of sub pixels including an emission area and a non-emission area; a metal layer on the substrate, the metal layer including a plurality of wiring lines and a light shielding layer that are on the substrate; and a transmission reduction layer that reduces transmission of external light, the transmission reduction layer including a conductive material and has a first surface that is black and less smooth than a second surface of the transmission reduction layer, wherein the transmission reduction layer is between the metal layer and the substrate such that the transmission reduction layer overlaps the metal layer.

In one embodiment, the transmission reduction layer includes a first transmission reduction layer that overlaps the plurality of wiring lines and a second transmission reduction layer that overlaps the light shielding layer.

In one embodiment, the metal layer further includes a gate line on the substrate and the transmission reduction layer further includes a third transmission reduction layer that overlaps the gate line and is electrically connected to the gate line.

In one embodiment, the display device further comprises an over coating layer on the substrate, the over coating layer including a plurality of micro lenses on the emission area of at least one of the plurality of sub pixels, wherein the transmission reduction layer further includes a fourth transmission reduction layer that overlaps the plurality of micro lenses.

In one embodiment, the fourth transmission reduction layer includes a plurality of fourth transmission reduction layers that are connected to each other.

In one embodiment, the fourth transmission reduction layer is electrically connected to the second transmission reduction layer.

In one embodiment, the display device further comprises a lens transmission reduction layer on the over coating layer, the lens transmission reduction layer overlapping the plurality of micro lenses; and a plurality of light emitting diodes on the substrate, each of the plurality of light emitting diodes including an anode, an emission layer on the anode, and a cathode on the emission layer, wherein the lens transmission reduction layer is on a same layer as the anode.

In one embodiment, a display device comprises: a substrate; a conductive transmission reduction layer that is in contact with an upper surface of the substrate, the conductive transmission reduction layer having a first surface and a second surface that is smoother than the first surface and the first surface is less transmissive of external light than the second surface; a metal layer directly on the first surface of the conductive transmission reduction layer such that the conductive transmission reduction layer is between the metal layer and the substrate; a transistor on the substrate; and a light emitting element that emits light, the light emitting element electrically connected to the transistor.

In one embodiment, the metal layer includes at least one of a power line, a data line, or a reference line and the conductive transmission reduction layer is between the substrate and at least one of the power line, the data line, or the reference line.

In one embodiment, the metal layer includes a gate line and the conductive transmission reduction layer is between the gate line and the substrate.

In one embodiment, the gate line is electrically connected to the conductive transmission reduction layer.

In one embodiment, the metal layer includes at least a portion of the transistor and the conductive transmission reduction layer is between the portion of the transistor and the substrate.

In one embodiment, the metal layer includes a light shielding layer and the conductive transmission reduction layer is between the light shielding layer and the substrate.

In one embodiment, the display device further comprises an over coating layer on the substrate, the over coating layer including a plurality of micro lenses, wherein the conductive transmission reduction layer overlaps the plurality of micro lenses.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device comprising:
a substrate;
a plurality of sub pixels on the substrate, each of the plurality of sub pixels including an emission area and a non-emission area;
a metal layer on the substrate, the metal layer closer to the substrate than other metal layers of the display device; and
a transmission reduction layer that reduces transmission of external light, the transmission reduction layer between the metal layer and the substrate and having a first surface that is black and less smooth than a second surface of the transmission reduction layer.

2. The display device according to claim 1, wherein the transmission reduction layer includes a conductive material.

3. The display device according to claim 1, wherein the metal layer includes a plurality of wiring lines on the substrate and the transmission reduction layer overlaps the plurality of wiring lines.

4. The display device according to claim 1, wherein the plurality of sub pixels includes a plurality of transistors on the substrate, the metal layer is between the plurality of transistors and the substrate such that the metal layer overlaps the plurality of transistors, and the transmission reduction layer overlaps the metal layer and the plurality of transistors.

5. The display device according to claim 4, wherein the metal layer further includes a gate line on the substrate and the transmission reduction layer that overlaps the plurality of transistors also overlaps the gate line.

6. The display device according to claim 3, wherein the metal layer further includes a gate line on the substrate and another transmission reduction layer overlaps the gate line such that the other transmission reduction layer is spaced apart from the transmission reduction layer that overlaps the plurality of wiring lines.

7. The display device according to claim 6, wherein the other transmission reduction layer that overlaps the gate line is electrically connected to the gate line.

8. The display device according to claim 1, further comprising:
an over coating layer on the substrate, the over coating layer including a plurality of micro lenses on the emission area of at least one of the plurality of sub pixels.

9. The display device according to claim 8, wherein the transmission reduction layer overlaps the plurality of micro lenses.

10. The display device according to claim 9, wherein the transmission reduction layer that overlaps the plurality of micro lenses is connected to another transmission reduction layer.

11. The display device according to claim 10, wherein the metal layer further includes a gate line on the substrate, and the other transmission reduction layer overlaps the gate line and is electrically connected to the transmission reduction layer that overlaps the plurality of micro lenses.

12. The display device according to claim 8, further comprising:
a lens transmission reduction layer on the over coating layer, the lens transmission reduction layer overlapping the plurality of micro lenses.

13. The display device according to claim 12, further comprising:
a plurality of light emitting diodes on the substrate, each of the plurality of light emitting diodes including an anode, an emission layer on the anode, and a cathode on the emission layer,
wherein the lens transmission reduction layer is on a same layer as the anode.

14. A display device comprising:
a substrate;
a plurality of sub pixels on the substrate, each of the plurality of sub pixels including an emission area and a non-emission area;
a metal layer on the substrate, the metal layer including a plurality of wiring lines and a light shielding layer that are on the substrate; and
a transmission reduction layer that reduces transmission of external light, the transmission reduction layer including a conductive material and has a first surface that is black and less smooth than a second surface of the transmission reduction layer,
wherein the transmission reduction layer is between the metal layer and the substrate such that the transmission reduction layer overlaps the metal layer.

15. The display device according to claim 14, wherein the transmission reduction layer includes:
a first transmission reduction layer that overlaps the plurality of wiring lines; and
a second transmission reduction layer that overlaps the light shielding layer.

16. The display device according to claim 15, wherein the metal layer further includes a gate line on the substrate and the transmission reduction layer further includes a third transmission reduction layer that overlaps the gate line and is electrically connected to the gate line.

17. The display device according to claim 16, further comprising:
an over coating layer on the substrate, the over coating layer including a plurality of micro lenses on the emission area of at least one of the plurality of sub pixels,
wherein the transmission reduction layer further includes a fourth transmission reduction layer that overlaps the plurality of micro lenses.

18. The display device according to claim 17, wherein the fourth transmission reduction layer includes a plurality of fourth transmission reduction layers that are connected to each other.

19. The display device according to claim 18, wherein the fourth transmission reduction layer is electrically connected to the second transmission reduction layer.

20. The display device according to claim 17, further comprising:
a lens transmission reduction layer on the over coating layer, the lens transmission reduction layer overlapping the plurality of micro lenses; and
a plurality of light emitting diodes on the substrate, each of the plurality of light emitting diodes including an anode, an emission layer on the anode, and a cathode on the emission layer,
wherein the lens transmission reduction layer is on a same layer as the anode.

21. A display device comprising;
a substrate;
a conductive transmission reduction layer that is in contact with an upper surface of the substrate, the conductive transmission reduction layer having a first surface and a second surface that is smoother than the first surface and the first surface is less transmissive of external light than the second surface;
a metal layer directly on the first surface of the conductive transmission reduction layer such that the conductive transmission reduction layer is between the metal layer and the substrate;
a transistor on the substrate; and
a light emitting element that emits light, the light emitting element electrically connected to the transistor.

22. The display device of claim 21, wherein the metal layer includes at least one of a power line, a data line, or a reference line and the conductive transmission reduction layer is between the substrate and at least one of the power line, the data line, or the reference line.

23. The display device of claim 21, wherein the metal layer includes a gate line and the conductive transmission reduction layer is between the gate line and the substrate.

24. The display device of claim 23, wherein the gate line is electrically connected to the conductive transmission reduction layer.

25. The display device of claim 21, wherein the metal layer includes at least a portion of the transistor and the conductive transmission reduction layer is between the portion of the transistor and the substrate.

26. The display device of claim 21, wherein the metal layer includes a light shielding layer and the conductive transmission reduction layer is between the light shielding layer and the substrate.

27. The display device of claim 21, further comprising:
an over coating layer on the substrate, the over coating layer including a plurality of micro lenses,
wherein the conductive transmission reduction layer overlaps the plurality of micro lenses.
